(19) United States
(12) Patent Application Publication
(10) Pub. No.: US 2021/0074321 A1
(43) Pub. Date: Mar. 11, 2021

(54) MANUFACTURING METHOD OF MAGNETIC DISK DEVICE AND MAGNETIC DISK DEVICE

(71) Applicants: Kabushiki Kaisha Toshiba, Tokyo (JP); Toshiba Electronic Devices & Storage Corporation, Tokyo (JP)

(72) Inventors: Hidetoshi Tsuneda, Yamato Kanagawa (JP); Kenji Yoshida, Kamakura Kanagawa (JP)

(21) Appl. No.: 16/810,460

(22) Filed: Mar. 5, 2020

(30) Foreign Application Priority Data
Sep. 11, 2019 (JP) 2019-165007

(51) Int. Cl. G11B 5/29; G11B 5/55; G01R 21/06

(52) U.S. Cl. CPC G11B 5/295; G01R 21/06; G11B 5/5526

(57) ABSTRACT

According to one embodiment, a manufacturing method of a magnetic disk device including a magnetic disk that stores information, and two or more control devices is provided. The method includes acquiring power consumption of each of a plurality of control devices to be able to be included in the magnetic disk device; and selecting a combination of two or more control devices to reduce variation in total power consumption, on the basis of the acquired power consumption.

### CROSS-REFERENCE TO RELATED APPLICATIONS

This application is based upon and claims the benefit of priority from Japanese Patent Application No. 2019-165007, filed on Sep. 11, 2019; the entire contents of which are incorporated herein by reference.

### FIELD

Embodiments described herein relate generally to a manufacturing method of a magnetic disk device and a magnetic disk device.

### BACKGROUND

Conventionally, there are magnetic disk devices that store information and include two or more control devices, such as a large scale integrated circuit (LSI).

However, such control devices vary in power consumption due to individual differences having occurred in the manufacturing process. Thus, the control devices of the magnetic disk device differ in total power consumption, so that there is room for improvement.

### BRIEF DESCRIPTION OF THE DRAWINGS

FIG. 1 is an overall configuration diagram of a magnetic disk device according to a first embodiment;

FIG. 2 is a diagram for explaining the trajectory of magnetic heads according to the first embodiment;

FIG. 3 is a configuration diagram of an LSI according to the first embodiment;

FIG. 4 is a flowchart illustrating the procedure of a test during manufacturing in the first embodiment;

FIG. 5 is a flowchart illustrating the procedure of mounting LSIs on a substrate in the first embodiment;

FIG. 6 is a flowchart illustrating the procedure of a test during manufacturing in a second embodiment;

FIG. 7 is a flowchart illustrating the procedure of mounting LSIs on a substrate in the second embodiment; and

FIG. 8 is an overall configuration diagram of a magnetic disk device according to a third embodiment.

### DETAILED DESCRIPTION

According to one embodiment, in general, a manufacturing method of a magnetic disk device including a magnetic disk that stores information, and two or more control devices is provided. The method includes acquiring power consumption of each of a plurality of control devices to be able to be included in the magnetic disk device; and selecting a combination of two or more control devices to reduce variation in total power consumption, on the basis of the acquired power consumption.

Magnetic disk devices of first to fourth embodiments will be explained below in detail with reference to the accompanying drawings. The embodiments are merely exemplary and not intended to limit the scope of the present invention.

### First Embodiment

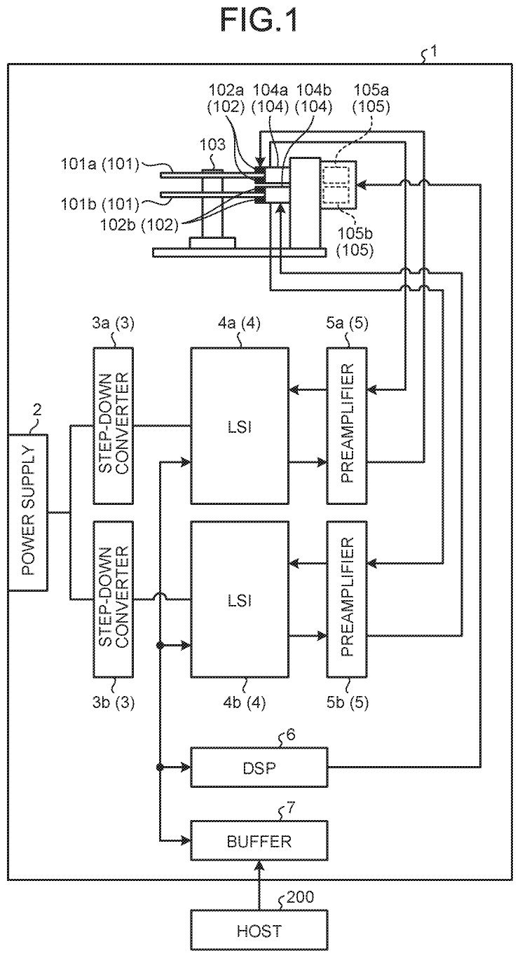

FIG. 1 is an overall configuration diagram of a magnetic disk device 1 according to a first embodiment. As illustrated in FIG. 1, the magnetic disk device 1 includes two magnetic disks 101, two magnetic head pairs 102 that read and write data, and two actuators 104 that move the respective magnetic head pairs 102. In FIG. 1, the lines connecting between elements indicate major connection relations, and elements not connected by the lines may be connected to one another.

The two magnetic disks 101 include a magnetic disk 101a and a magnetic disk 101b. The two magnetic head pairs 102 include a magnetic head pair 102a (first magnetic head) and a magnetic head pair 102b (second magnetic head). The two actuators 104 include a first actuator 104a and a second actuator 104b.

The two magnetic disks 101 are attached to a rotary shaft 103 of a spindle motor with a certain pitch along the axis of the rotary shaft 103. The two magnetic disks 101 are rotated together at the same rotating speed along with the rotation of the rotary shaft 103. The number of magnetic disks 101 of the magnetic disk device 1 is not limited to two.

The magnetic heads 102a are individually mounted on the front side and back side of the magnetic disk 101a. The magnetic heads 102a are attached to the distal end of the first actuator 104a. The magnetic heads 102a write and read a signal corresponding to data to and from the magnetic disk 101a.

The magnetic heads 102b are individually mounted on the front side and back side of the magnetic disk 101b. The magnetic heads 102b are attached to the distal end of the second actuator 104b. The magnetic heads 102b write and read a signal corresponding to data to and from the magnetic disk 101b.

The magnetic disk device 1 includes two voice coil motors (VCMs) 105. The two VCMs 105 include a VCM 105a and a VCM 105b.

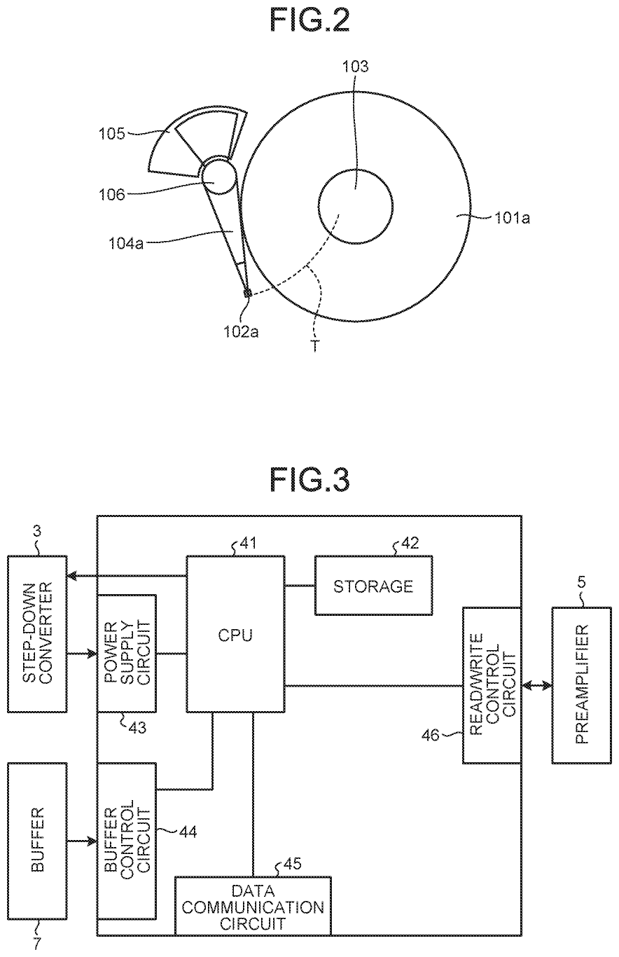

The first actuator 104a is rotated by the VCM 105a about a shaft 106 (FIG. 2).

FIG. 2 is a diagram for explaining the trajectory of the magnetic heads 102a according to the first embodiment. FIG. 2 depicts the magnetic head 102a from the magnetic disk 101a side in the extending direction of the shaft 106 in FIG. 1.

As illustrated in. FIG. 2, the first actuator 104a is rotated by the VCM 105a within a predefined range about the shaft 106, to be able to move the magnetic head 102a along the broken line T. The magnetic heads 102a are then positioned on any of the tracks of the magnetic disk 101a in the radial direction.

The second actuator 104b is rotated by the VCM 105b about the shaft 106. As with the first actuator 104a, the second actuator 104b is also driven by the VCM 105b. Thereby, the magnetic heads 102b and the magnetic heads 102a can be moved along substantially the same tracks.

Referring back to FIG. 1, the magnetic disk device 1 further includes a power supply 2, two step-down converters 3, two large scale integrated circuits (LSIs) 4, two preamplifiers 5, a digital signal processor (DSP) 6, and a buffer 7.

The power supply 2 receives electric power from, for example, an external power supply (not illustrated) and supplies it to the step-down converters 3 and the other elements of the magnetic disk device 1.

The two step-down converters 3 include a step-down converter 3a and a step-down converter 3b. Specifically, the step-down converters 3 are step-down DC/DC (direct current) converters to step down an input current from the power supply 2 and supply the resultant current to the corresponding LSIs 4. The step-down converter 3a steps down an input current from the power supply 2 and supplies the resultant current to the LSI 4a. The step-down converter 3b steps down an input current from the power supply 2 and supplies the resultant current to the LSI 4b.

The two LSIs 4 include the LSI 4a (first control device) and the LSI 4b (second control device). The LSIs 4 are, for example, system-on-a-chips (SoC), i.e., large-scale integrated circuits, two or more elements integrated on a single chip. FIG. 3 is a configuration diagram of the LSI 4 according to the first embodiment.

As illustrated in FIG. 3, the LSI 4 includes a central processing unit (CPU) 41, a storage 42, a power supply circuit 43, a buffer control circuit 44, a data communication circuit 45, and a read/write control circuit 46. In FIG. 3, the lines connecting between elements indicate major connection relations, and elements not connected by the lines may be connected to one another.

The CPU 41 serves as a processor that executes a program. For example, the CPU 41 receives from the host 200 commands such as a read command and a write command stored in the buffer 7 and translates them to monitor and/or control the state of the respective elements of the magnetic disk device 1. The host 200 serves as, for example, a processor, a personal computer, or a server.

The storage 42 is means for storing various kinds of management, information, and includes, for example, a nonvolatile memory such as a flash memory and/or a volatile memory such as a static random access memory (SRAM) or dynamic random access memory (DRAM).

The power supply circuit 43 supplies an input current from the corresponding step-down converter 3 to the respective elements inside the LSI 4.

The buffer control circuit 44 controls access to the buffer 7.

The data communication circuit 45 controls communication with the other LSI 4.

The read/write control circuit 46 controls writing and reading to and from the magnetic disk 101 through the preamplifier 5. For example, the read/write control circuit 46 converts digital data into a signal to be supplied to the magnetic heads 102, and converts a signal output from the magnetic heads 102 into digital data. The read/write control circuit 46 is referred to as a read/write channel.

Referring back to FIG. 1, the two preamplifiers 5 include a preamplifier 5a and a preamplifier 5b. The preamplifiers 5 serve to amplify a signal, read by the magnetic heads 102 (read element) from the magnetic disk 101, and supplies the resultant signal to the read/write control circuits 46 (FIG. 3). The preamplifiers 5 receive and amplify a signal from the corresponding read/write control circuits 46, and supply the signal to the magnetic heads 102 (write element).

The DSP 6 controls the spindle motor and the VCMs 105a and 105b for positioning control over the magnetic heads 102, such as seeking and following.

The buffer 7 serves as a temporary storage area for data transmission and reception to and from the host 200. In other words, data received from the host 200 is temporarily stored in the buffer 7. Data to be transmitted from the magnetic disks 101 to the host 200 is temporarily stored in the buffer 7.

As described above, control devices such as LSIs vary in power consumption due to individual differences having occurred in the manufacturing process. Conventionally, in magnetic disk devices incorporating two or more control devices such as LSIs, the control devices differ in total power consumption; thus, there is room for improvement. Specifically, in the case of a magnetic disk device 1 incorporating LSIs that consume larger power, for example, the magnetic disk device 1 may exhibit a large temperature rise during operation due to large power consumption, and run into thermal runaway, i.e., malfunction caused by a high temperature.

In view of this, the following will describe reducing the total power consumption of multiple control devices of a magnetic disk device.

A manufacturing method of the magnetic disk device 1 according to the first embodiment includes a calculation (example of acquisition) process and a selection process. A large number of LSIs 4 are prepared. to decide the ones to be applied to one magnetic disk device 1. In the calculation process, the power consumption of each of the LSIs 4 is calculated. In the selection process, a combination of LSIs is selected to reduce variations in the total power consumption, on the basis of the power consumption calculated in the calculation process. More specifically, the calculation process and the selection process are as follows.

In the calculation process the power consumption of each of LSIs to be usable as the LSI 4a and LSI 4b is calculated. In the selection process, a combination of two LSIs to become the LSI 4a and LSI 4b are selected from the LSIs to reduce variations in the total power consumption of the two LSTs, on the basis of the power consumption calculated in the calculation process. Hereinafter, an LSI to be applied will also be referred to as LSI 4.

The manufacturing method further includes a process of acquiring the current value of each of the LSIs 4 in a current test In this case, in the calculation process the power consumption of each of the LSIs is calculated from the acquired current value in the acquiring process.

This manufacturing method further includes a process of acquiring the operable voltage value of each of the LSIs 4 in a function test. In this case, in the calculation process the power consumption of each of the LSIs is calculated from the acquired current value in the current acquiring process and the acquired operable voltage in the voltage acquiring process.

Further, the LSI 4a and LSI 4b in the magnetic disk device 1 manufactured by this manufacturing method each include a storage (storage 42 in FIG. 3) that stores the power consumption estimated in the test.

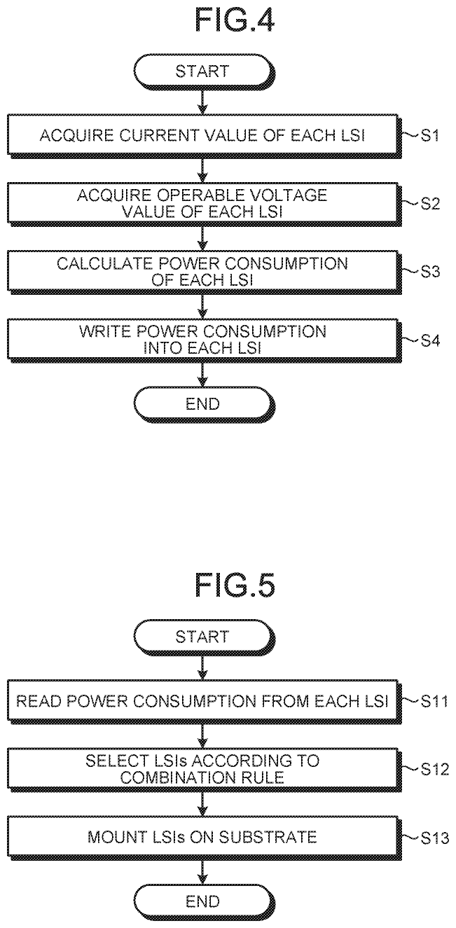

Next, with reference to FIG. 4, the procedure of the manufacturing test in the first embodiment will be described. FIG. 4 is a flowchart illustrating the procedure of the manufacturing test in the first embodiment.

First, in step S1, for example, in a current test of the manufacturing test, a given device being a test device such as an ammeter is prepared to measure the current value of each LSI 4. Specifically, the given device acquires the current value of each LSI 4 by IDD testing and/or IDDQ testing, for example. In such testing, a given power supply is set to the VDD terminal of the LSI 4a, and input pins are set thereto to place the inside of the LSI 4 in a specific operation state. Then, the given device measures a value of current passing through the LSI 4.

IDD testing is a method for measuring the current (dynamic current) across the LSI 4 while maintained in an active state by continuous input of an adjustment pattern (test pattern) thereto. IDDQ testing is a method for measuring the current (leakage current) across the LSI 4 while maintained in a stationary state. Such testing enables the measurement of the current value inside the LSI 4.

The IDD testing may be omissible. The IDDQ testing alone may be sufficient to measure the current value as long as fluctuation in the dynamic current due to variations is extremely small as compared with fluctuation in the leakage current.

In step S2, for example, the given device acquires the operable voltage value of each. LSI 4 in a function test of the manufacturing test. Specifically, in the manufacturing test, the function test is conducted to check whether the LSI 4 operates as designed. In the first embodiment, adaptive voltage scaling (AVS) is applied. AVS refers to a method of supplying an optimum voltage depending on individual differences among the LSIs 4 and/or operational environment such as temperature.

For this purpose, the LSIs 4 are subjected to the function test under the following setting conditions to find out from what voltage value the LSTs 4 become operable,

(1) Frequency: set to the maximum frequency in the specification.

(2) Voltage value: lower-limit value and upper-iimit value are defined to set a voltage value within the defined range.

As regards the voltage value, first, the operation of the LSI 4 is tested at the lower-limit value. When the LSI 4 operates expectedly, the operable voltage value of the LSI 4 is set to the lower-limit value. If the LSI 4 is inoperable at the lower-limit value, the LSI 4 is subjected to the test again at an increased voltage value. This operation is repeated until the upper-limit value to find the operable voltage value of the LSI 4. With a smaller increment in the voltage value, the operable voltage value is improved in terms of granularity, however, the test time is elongated. Thus, it is preferable to set the increment in voltage value in consideration of this trade-off relation.

Next, in step S3, the given device calculates the power consumption, i.e., estimate of power consumption of each LSI 4. Specifically, the given device calculates the power consumption of the LSIs 4 when mounted on the substrate by the following formula (1):

Power consumption=F

where F (result of manufacturing test) represents a function having results of the manufacturing test as current value and/or operable voltage value as variables. By AVS, the storage of the LSI 4 stores the operable voltage value, so that this operable voltage value is usable.

In step S4, the given device writes the power consumption calculated in step S3 into nonvolatile memories, such as an e-fuse (electronic fuse), of the storages 42 of the corresponding LSIs 4.

Next, with reference to FIG. 5, the procedure of mounting the LSIs 4 on the substrate in the first embodiment will be described. FIG. 5 is a flowchart illustrating the procedure of mounting the LSIs 4 on the substrate in the first embodiment. First, in step S11, a given device (for use in mounting the LSIs 4) is prepared. to read the stored power consumption from the nonvolatile memory of the storage 42 of each LSI 4.

In step S12, the given device selects LSIs 4 according to a first combination rule. The first combination rule is defined for reducing variations in the total power consumption of the two LSIs 4. Such a combination rule may be, for example, such that a large number of LSIs 4 are classified into two or more classes by power consumption, and LSIs 4 in a larger power consumption class or LSIs 4 in a smaller power consumption class are avoided from being combined together.

Next, in step S13, an operator mounts the two LSIs 4 selected in step S12 on the same substrate.

As described above, according to the magnetic disk device 1 of the first embodiment, by selecting a combination of two LSIs 4 according to the power consumption of each of the LSIs 4 and the combination rule, it is possible to reduce variations in the total power consumption of the LSIs 4 mounted on the magnetic disk device 1.

Further, the power consumption of each LSI 4 is calculated, additionally using the operable voltage value of each LSI 4 obtained by AVS, thereby improving the accuracy of the power consumption. This enables further reduction in variations in the total power consumption. During the operation of the magnetic disk device 1, the operable voltage value stored in the storage 42 of each LSI 4 is fed back to the step-down converter 3 by AVS.

### Second Embodiment

Next, a second embodiment will be explained. Herein, repetitive explanations of the features similar to those of the first embodiment will be omitted. The second embodiment differs from the first embodiment in non-use of AVS. That the power consumption of each LSI 4 is calculated on the assumption that the same voltage value is supplied to the respective LSIs 4.

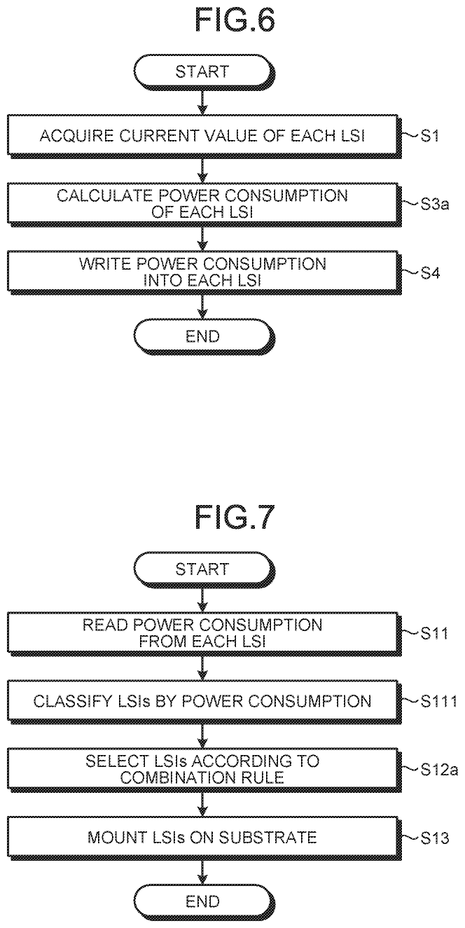

FIG. 6 is a flowchart illustrating the procedure of the manufacturing test in the second embodiment. First, in step S1, for example, a given device (test device) acquires the current value of each LSI 4 through the current test of the manufacturing test.

In step S3a, the given device calculates the power consumption, i.e., estimate of power consumption of each LSI 4. Unlike step S3 of FIG. 4, the same voltage value is applied to the respective LSIs 4.

Next, in step S4, the given device writes the power consumption calculated in step S3a to the nonvolatile memories of the storages 42 of the corresponding LSIs 4.

FIG. 7 is a flowchart illustrating the procedure of mounting the LSIs 4 on the substrate in the second embodiment. First, in step S11, a given device (for use in the mounting) reads the stored power consumption from the nonvolatile memory of the storage 42 of each LSI 4.

In step S111, the LSIs 4 are classified into classes by the power consumption. This is manually performed by an operator, for example. The operator applies physical marking onto the LSIs 4 consuming larger power among the large number of LSIs 4, for example.

Next, in step S12a, the operator selects LSIs 4 according to a second combination rule. The second combination rule is defined to reduce variations in the total power consumption of the two LSIs 4. Such a combination rule may be, for example, such that if the two selected LSIs 4 are both applied with the marking, one of the LSIs 4 is replaced with an LSI 4 with no marking.

In step S13, the operator mounts the two LSIs 4 selected in step S12a on the same substrate.

As described above, according to the magnetic disk device 1 of the second embodiment, by selecting a combination of two LSIs 4 according to the power consumption of each of the LSIs 4 and the combination rule, it is possible to reduce variations in the total power consumption of the LSIs 4 to mount on the magnetic disk device 1.

Further, applying the same voltage value for calculation of the power consumption leads to simplifying the operations and processes.

The above embodiment has described the example that among the large number of LSIs 4, the LSIs 4 with larger power consumption are applied with physical marking. However, the embodiment is not limited to such an example. Alternatively, a large number of LSIs 4 may be physically classified in advance into two or more classes by the magnitude of power consumption, for example. In this case, to select two LSIs 4, setting a combination of LSIs 4 in a larger power consumption class may be avoided. In addition, to select two LSIs 4, setting a combination of LSIs 4 in a smaller power consumption class may be avoided. This enables the magnetic disk devices 1 to be uniform in quality.

### Third Embodiment

Next, a third embodiment will be explained. Herein, repetitive explanations of the features similar to those of the first embodiment will be omitted. The third embodiment differs from the first embodiment in including a single step-down converter 3.

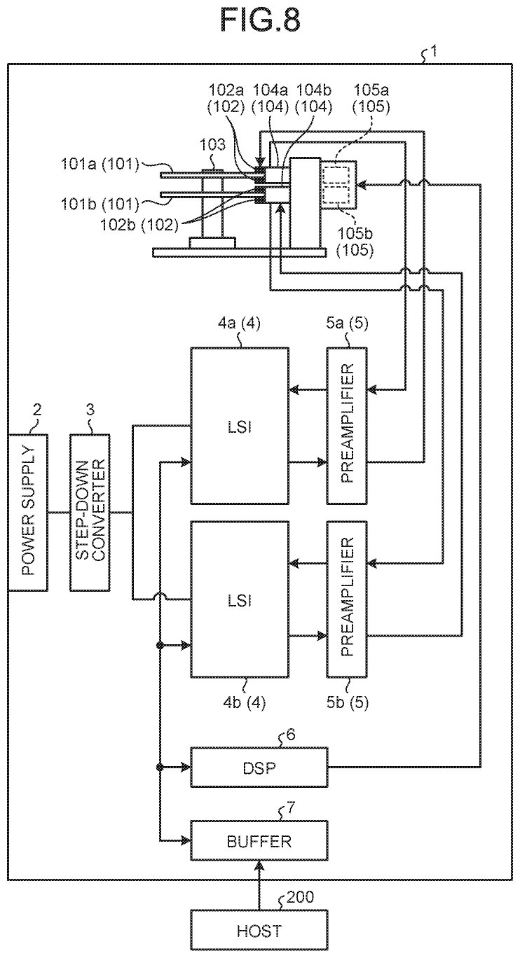

FIG. 8 is an overall configuration diagram of a magnetic disk device 1 according to the third embodiment. The magnetic disk device 1 includes a single step-down converter 3, and the two LSIs 4a and 4b are supplied with electric power from the single step-down converter 3.

In this case, by AVS, the two LSTs 4a and 4b are both applied with a voltage being a higher one of their operable voltage values, for example. That is, the power consumption of each LSI 4 can be calculated in consideration of this setting.

As described above, according to the magnetic disk device 1 of the third embodiment including the single step-down converter 3, a combination of two LSIs 4 is selected in view of the single step-down converter 3, thereby making it possible to reduce variations in the total power consumption thereof.

### Fourth Embodiment

Next, a fourth embodiment will be explained. Herein, repetitive explanations of the features similar to those of the first embodiment will be omitted. In the first embodiment, the LSIs 4a and LSIs 4b of FIG. 1 are of the same type. The fourth embodiment differs from the first embodiment in that the LSIs 4a and LSIs 4b are of different types.

in this case, first, the LSIs of the LSI 4 type are divided into classes by power consumption. Similarly, the LSIs of the LSIs 4b type are divided into classes by power consumption.

Then, the LSIs of different types are selected one by one not to make a combination of two LSIs of a larger power consumption class.

Thus, according to the magnetic disk device 1 of the fourth embodiment, the LSIs 4 of different types can be mounted on one magnetic disk device 1 to be able to reduce variations in the total power consumption by the method described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the first to fourth embodiments have described the example that one magnetic disk device 1 includes two LSIs 4; however, the embodiments are not limited to such an example. One magnetic disk device 1 may include three or more LSIs 4.

Further, the above embodiments have described LSIs as an example of control devices; however, the embodiments are not limited to such an example. Any of the embodiments may be applicable to another control device, such as integrated circuit (IC).

Further, in FIG. 1, the DSP 6 may be incorporated into each LSI 4. The ISIS 4 may communicate with the host 200.

What is claimed is:

1. A manufacturing method of a magnetic disk device comprising a magnetic disk that stores information, and two or more control devices, the method comprising:
acquiring power consumption of each of a plurality of control devices to be able to be included in the magnetic disk device; and
selecting a combination of two or more control devices to reduce variation in total power consumption, on the basis of the acquired power consumption.

2. A manufacturing method of a magnetic disk device comprising a magnetic disk that stores information, a first actuator that moves a first magnetic head, a second actuator that moves a second magnetic head, a first control device that controls the first actuator, and a second control device that controls the second actuator, the method comprising:
acquiring power consumption of each of a plurality of control devices to be usable as the first control device and the second control device; and
selecting, from the control devices, a combination of two control devices as the first control device and the second control device to reduce variation in total power consumption of the two control devices, on the basis of the acquired power consumption.

3. The manufacturing method of a magnetic disk device according to claim 2, further comprising
acquiring a current value of each of the control devices in a current test, wherein
in the acquiring, the power consumption of each of the control devices is acquired from the acquired current value.

4. The manufacturing method of a magnetic disk device according to claim 3, further comprising
acquiring an operable voltage value of each of the control devices in a function test, wherein
in the acquiring, the power consumption of each of the control devices is acquired from the acquired current value and the acquired operable voltage.

5. A magnetic disk device comprising:
a magnetic disk that stores information;
a first actuator that moves a first magnetic head;
a second actuator that moves a second magnetic head.;
a first control device that controls the first actuator; and
a second control device that controls the second actuator, wherein
the first control device and the second control device each comprise storage that stores power consumption estimated in a test.
